(19) United States
(12) Patent Application Publication
(10) Pub. No.: US 2013/0287963 A1
(43) Pub. Date: Oct. 31, 2013

(54) Plasma Potential Modulated ION Implantation Apparatus

(71) Applicants: Svetlana B. Radovanov, Brookline, MA (US); Ludovic Godet, Boston, MA (US); Bon-Woong Koo, Andover, MA (US); Timothy J. Miller, Ipswich, MA (US)

(72) Inventors: Svetlana B. Radovanov, Brookline, MA (US); Ludovic Godet, Boston, MA (US); Bon-Woong Koo, Andover, MA (US); Timothy J. Miller, Ipswich, MA (US)

(73) Assignee: VARIAN SEMICONDUCTOR EQUIPMENT ASSOCIATES, INC., Gloucester, MA (US)

(21) Appl. No.: 13/457,455

(22) Filed: Apr. 26, 2012

(51) Int. Cl. C23C 14/48

(52) U.S. Cl. 427/523; 118/719

(57) ABSTRACT

An ion implantation apparatus including a first plasma chamber, a second plasma chamber and an extraction electrode disposed therebetween. The first and second plasma chambers configured to house respective plasmas in response to the introduction of a different feed gases therein. The extraction electrode is electrically isolated from the plasma chamber. An extraction voltage is applied to the first plasma chamber above a bias potential used to generate the plasma therein. The extraction voltage drives the plasma potential to accelerate the ions in the first plasma to a desired implant energy. The accelerated ions pass through an aperture in the extraction electrode and are directed toward a substrate housed within the second plasma chamber for implantation.

### BACKGROUND

This invention relates generally to the implantation of substrates. More particularly, the present invention relates to precise dopant placement and/or precision material modification of conductive, insulating substrates and semiconductor substrates used for fabrication of solar cells, flat panel devices, LEDs, image sensors, and other devices.

Ion implantation is a standard technique for introducing property-altering impurities into substrates. A desired impurity material is ionized in an ion source, the ions are accelerated to form an ion beam of prescribed energy, and the ion beam is directed at the surface of the substrate. The energetic ions in the beam penetrate into the sub-surface of the substrate material and are embedded into the crystalline lattice of the substrate material to form a region of desired conductivity or material property.

Localized or selective doping or localized or selective material modification may be required for some implants. For example, fabrication of solar cell devices and/or manufacturing of flat panel devices present examples in which high dose implantation and selective doping of local areas are desirable. These high dose implantation applications require relatively high-throughput to provide an alternative to competitive fabrication techniques and systems and to contribute to the lowest cost-of-ownership for an ion implantation system. However, high-volume production for implant applications for these devices confronts significant challenges due, in part, to “glitching” in the extraction region. Generally, “glitching” refers to the interruption in beam current of an ion beam incident on a surface of a substrate. More particularly, glitching is a sudden transient in the beam current that may adversely affect dose uniformity of implant species on a target substrate.

Another challenge for ion beam processing of insulated substrates is the need to dissipate charge which may occur during ion implantation because of the fact that ions impinging on the substrate by nature carry charge. In the case of ion beams that comprise positive ions, positive charge may build up on the substrate after exposure to the ion beam. In order for this charge to be dissipated, the substrate holder or platen may be grounded, thereby providing a conductive path for conducting the charge from the substrate surface. However, if the substrate itself is a poor conductor or an electrical insulator, and/or if there is poor electrical backside contact, the charge on the substrate surface may have no conductive path to ground, thereby preventing the charge from being dissipated.

Certain ion implantation systems suffer from a lack of suppression in the extraction region where plasma in the source chamber is coupled with the ions incident on the surface of the substrate. This may cause source instability, glitching and beam current drift. To correct for these challenges, some ion implantation systems utilize various extraction electrode configurations including, for example, a suppression electrode, a focus electrode and a ground electrode to control the extracted beam quality and to suppress unwanted glitching. Although adding these components may mitigate these challenges, it also adds to system complexity and adversely affects cost of ownership of these implanters used for high-volume production. Accordingly, there is a need in the art for an improved implantation of workpieces and, more particularly, to an improved method and apparatus for implantation of substrates while avoiding ion beam glitching and mitigating surface charge build-up.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

Various embodiments are generally directed to an ion implantation apparatus. Some embodiments are particular directed to an ion implantation apparatus arranged to modulate a plasma potential within a chamber to accelerate ions in the plasma for implantation in a substrate. In one embodiment, a first plasma chamber is operable to produce first plasma in response to the introduction of a first gas. A second plasma chamber is also operable to produce second plasma which is inert, in response to the introduction of a second gas different from the first gas. An electrically conductive extraction electrode is disposed between the first and second plasma chambers. An extraction voltage is applied to the first plasma chamber to accelerate ions having certain characteristics, such as certain dopant characteristics, within the first plasma chamber. A high voltage sheath is defined between the first plasma and the extraction electrode since the extraction electrode is at ground potential with respect to the first plasma. The extraction electrode includes an aperture through which these accelerated ions are extracted into the second plasma chamber. These accelerated ions form an ion beam. A substrate is disposed within the second plasma chamber and is aligned with the aperture of the extraction electrode to provide implantation of the ions comprising the ion beam into the substrate.

In one embodiment, for example, a first bias voltage is applied to a plasma source to generate first plasma within a first plasma chamber. A second bias voltage is applied to a second plasma source within a second plasma chamber to generate second plasma. An extraction voltage is applied to the first plasma chamber to accelerate ions within the first plasma to desired implant energy. A workpiece is disposed within the second plasma chamber. An extraction electrode, disposed between the first and second plasma chambers, is at a lower potential than the plasma in the first chamber and is used to extract ions that form an ion beam propagating through a plasma in the second chamber. The extraction electrode directs the ion beam toward the workpiece for implantation therein.

### BRIEF DESCRIPTION OF THE DRAWINGS

FIG. 1 illustrates a schematic cross sectional view of an ion implantation processing apparatus.

FIG. 1A illustrates an exemplary voltage pulse train utilized by the implantation apparatus of FIG. 1.

FIG. 2 illustrates a schematic cross sectional view of an ion implantation processing apparatus.

FIG. 3 illustrates a schematic cross sectional view of an ion implantation processing apparatus.

FIG. 4 illustrates a schematic cross sectional view of an ion implantation processing apparatus.

FIG. 5 illustrates a schematic cross sectional view of an ion implantation processing apparatus.

FIG. 6 illustrates an embodiment of a logic flow for the operation of an ion implantation apparatus.

### DETAILED DESCRIPTION

Embodiments of an apparatus and method are described herein in connection with implantation of workpieces or substrates. In various embodiments, this apparatus can be used with, for example, solar cell substrates, semiconductor substrates, flat panels, and substrates comprising insulating material. The invention is not limited to the specific embodiments described below.

In various embodiments, an ion implantation apparatus includes a first plasma chamber, a second plasma chamber and an extraction electrode disposed there between. The first plasma chamber may utilize a plasma source to generate first plasma in response to the introduction of a first gas having desired properties, such as desired dopant properties. In various embodiments, the plasma may be generated within the first plasma chamber by RF discharge. An extraction voltage is applied to the first plasma chamber to accelerate ions within the plasma to desired implant energy. The extraction electrode may define a portion of the first plasma chamber and or a portion of the second plasma chamber, but is electrically isolated from the first plasma chamber and may be maintained at ground potential. In addition, the extraction electrode may be at the same potential as the second plasma chamber. The accelerated ions traverse a plasma sheath within the first plasma chamber defined between the first plasma and the extraction electrode. The accelerated ions having the desired trajectories pass through an aperture in the extraction electrode and form an ion beam. The ion beam passes through the second plasma chamber for implantation in a substrate or workpiece disposed at one end of the second plasma chamber. The second plasma within the second plasma chamber may be inert plasma based on the introduction of a second gas which is different from the first gas. The second plasma acts as a lens where the neutrals and ionized species are at a lower pressure than the first plasma in the first plasma chamber. The density of the second plasma is lower than the density of the ion beam formed by the accelerated ions extracted from the first plasma chamber. A pressure differential is maintained between the first plasma chamber and the second plasma chamber by a first pumping system attached to the first plasma chamber and a second pumping system attached to the second plasma chamber. This pressure differential allows the use of the two different gases introduced into the first and second plasma chambers respectively. Since the substrate or workpiece disposed within the second plasma chamber may be an insulating material such as, for example, a substrate having a polymer on its surface or a substrate having a large glass surface, and is surrounded by the inert plasma, the surface charge of the substrate which may be deleterious to the desired implant process is neutralized.

In various embodiments, the workpiece disposed within the second plasma chamber may be implanted at various implant energies based on the modulated plasma potential resulting from the application of the extraction voltage to the first plasma chamber. The first plasma chamber may be maintained at a uniform high pressure with respect to the second plasma chamber and the workpiece disposed therein which are maintained at a lower pressure. Since the second plasma chamber and the workpiece are maintained at ground potential, a field free region is defined between the extraction electrode and the workpiece. In this manner, the high voltage stress region is inside the first plasma chamber where the pressure is uniform which is decoupled from the pressure gradient located in the area defined between the extraction electrode and the workpiece in the second plasma chamber. This contributes to stable plasma operation. In addition, since the extraction electrode is a part of first plasma chamber but is electrically isolated from the first plasma chamber through the sheath within the first plasma chamber, the extraction electrode undergoes ion bombardment from the accelerated ions. This provides a means for self cleaning of the extraction electrode disposed between the first plasma chamber and the workpiece, thereby minimizing apparatus downtime related to deposition and/or flaking on the extraction electrode.

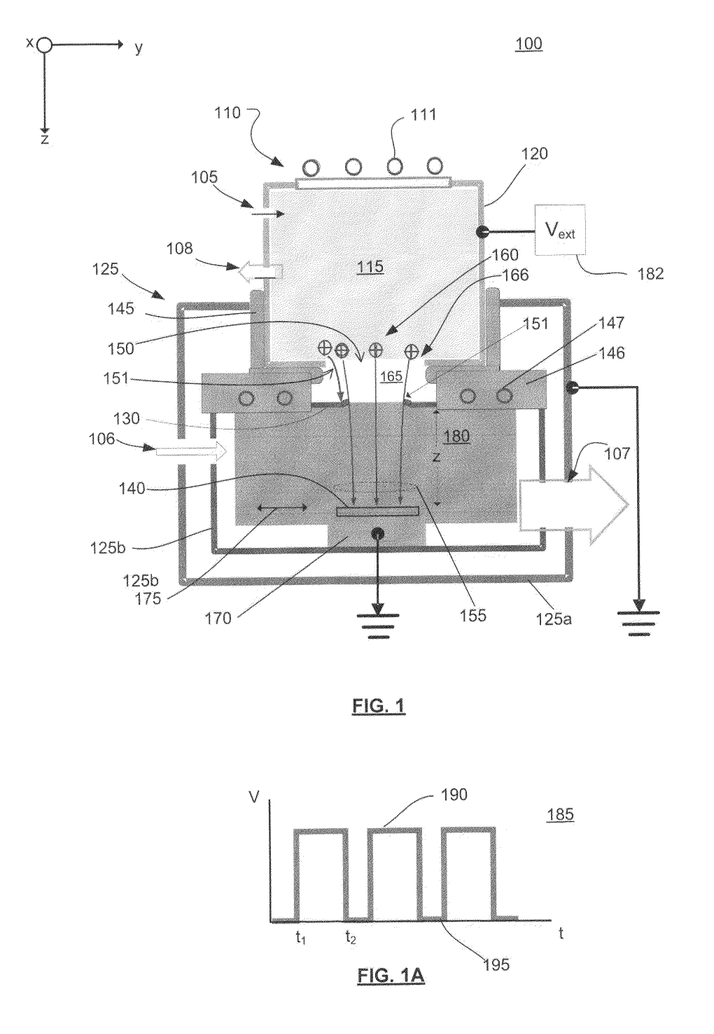

FIG. 1 illustrates a schematic cross sectional view of an ion implantation processing apparatus 100 including a first plasma chamber 120, a second plasma chamber 125 and an extraction electrode 130 disposed between the first and second plasma chambers. First plasma 115 is generated within first plasma chamber 120 in response to plasma source 110 and the introduction of a gas via port 105. An exhaust 108 is used to regulate the pressure within first plasma chamber 120 and in combination with port 105 defines a first pumping system associated with the first plasma chamber 120. In various embodiments, the plasma source 110 may be an RF plasma source, inductively-coupled plasma (ICP) source, or other plasma source known to those skilled in the art. However, in the exemplary embodiment shown in FIG. 1 the plasma source 110 may be an RF plasma source that includes RF antenna 111. The applied RF signal generated by the plasma source 110 may be pulsed or CW to generate the plasma 115 by RF discharge within first plasma chamber 120.

The extraction electrode 130 is disposed between the first plasma chamber 120 and the second plasma chamber 125. The extraction electrode 130 may be made from an electrically conductive material and is electrically isolated from the first plasma chamber 120 using insulated spacers 145. The extraction electrode 130 is electrically connected to the second plasma chamber 125. The extraction electrode 130 may include an aperture 150, through which accelerated ions 160 are extracted from first plasma chamber 120 toward substrate (or workpiece) 140 disposed within the second plasma chamber 125 for implantation therein. For example, extraction electrode 130 may be a unitary electrically conductive plate (e.g. graphite, silicon or silicon carbide) having an aperture 150 defining a gap having a horizontal spacing or width which may be, for example, 0.5-10 mm.

The second plasma chamber 125 is defined by an outer wall 125a and an inner wall 125b. The second plasma 180 is generated in response to the introduction of a gas, such as a dopant gas or an inert gas, within the inner wall 125b of the second plasma chamber 125 via port 106. A plasma source 146 associated with the second plasma chamber 125 is disposed at a first end of the plasma chamber 125. The plasma source 146 may be an RF plasma source, inductively-coupled plasma (ICP) source, or other plasma source known to those skilled in the art. In the exemplary embodiment shown in FIG. 1 the plasma source 146 may be an RF plasma source that includes RF antenna 147. The applied RF signal generated by the plasma source 146 may be pulsed or CW to generate the plasma 180 by RF discharge within second plasma chamber 125.

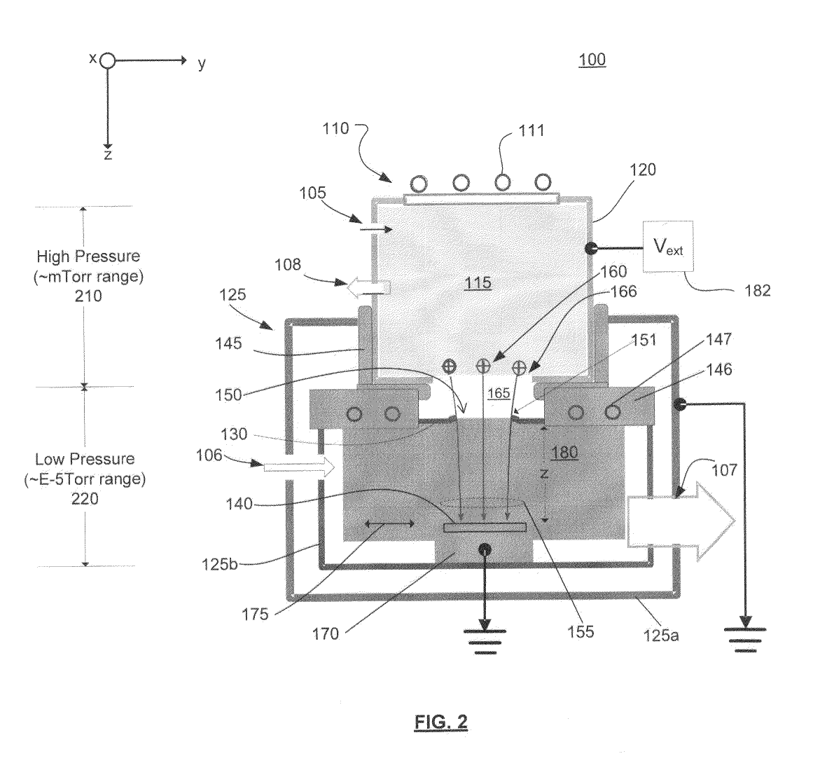

An exhaust port 107 extends from the outer wall 125a through inner wall 125b and is configured to regulate the pressure within second plasma chamber 125 as discussed in more detail with reference to FIG. 2. A pedestal or platen 170 is disposed within plasma chamber 125 and is configured to support one or more substrates 140 for implantation. Substrates 140 may be solar cells or other devices arranged on platen 170 which may use electrostatic clamping, mechanical clamping, or a combination of electrostatic and mechanical clamping to retain the substrates 140 in position. As used herein, substrate 140 or substrates 140 may refer to one or more substrates disposed on platen 170 which are exposed to ion beam 155. The substrate 140, aligned a distance away from extraction electrode 130, undergoes ion implantation and is displaced in either direction as indicated by arrow 175 and another substrate 140 is aligned with aperture 150 to undergo implantation and the process continues. The substrate 140 may be displaced in either direction indicated by arrow 175 by platen 170 in a continuous manner which provides uniform implantation to the substrate 140. Alternatively, a substrate 140 may be displaced in either direction indicated by arrow 175 by platen 170 in a stepwise fashion to provide, for example, patterned implantation to form structures such as a selective emitter.

A power source 182 is electrically connected to first plasma chamber 120 and is configured to apply an extraction voltage Vₑₓₜ to drive the plasma potential (Vₚ) of plasma 115 to a desired energy level. The extraction voltage Vₑₓₜ may be, for example, between 0.1-20 kV. A plasma sheath 165 is defined between a plasma boundary 166 and extraction electrode 130 due to the application of the extraction voltage Vₑₓₜ supplied by power source 182 to the first plasma chamber 120. In order to define this high voltage sheath 165 between the plasma boundary 166 and extraction electrode 130, the extraction electrode 130 is at ground potential. In addition, since the second plasma chamber 125, extraction electrode 130, and substrates 140 all may be at ground potential or any potential lower than the plasma potential (Vₚ), the plasma potential Vₚ is positively biased with respect thereto and may likewise be, for example 0.1-20 KV corresponding to the applied extraction voltage Vₑₓₜ. Based on the applied extraction voltage Vₑₓₜ, ions within plasma 115 are accelerated across the high voltage sheath 165 through aperture 150 to form beam 155. The accelerated ions 160 generated in first plasma chamber 120 may be, for example, a p-type dopant, an n-type dopant, or other species known to those skilled in the art based on the gas introduced via port 105. Since the accelerated ions 160 that form beam 155 are like charged, they tend to repel or diverge from one another as they travel through second plasma chamber 125 toward substrate 140. In order to control this divergence, extraction electrode 130 may be separated from substrates 140 by a distance “Z” referred to as an “extraction gap” which may be, for example, between 1 to 30 cm depending on the application. The extraction gap Z may be adjusted depending on the shape of extraction electrode 130 and more particularly the configuration of aperture 150 as well as the implant energy of the ions forming beam 155. FIG. 1a illustrates an exemplary pulse train 185 representing extraction voltage Vₑₓₜ used to drive the plasma potential Vₚ within first chamber 120 to a desired potential. In particular, voltage pulse train 185 includes “ON” portions 190 in which the extraction voltage Vₑₓₜ is supplied to the walls of first plasma chamber 120 and “OFF” portions 195 in which the extraction voltage Vₑₓₜ is not supplied to the walls of first plasma chamber 120. The ON portion 190 includes a pulse rise-time at t₁ and the pulse-OFF portion 195 has a pulse fall-time at t₂. The ON portion 190 includes a steady state duration defined between time t₂ and t₁. The pulse rise-time at t₁ plus the pulse fall-time at t₂ is less than 25% of the steady state duration of the ON portion 190 defined between time t₂ and t₁.

During the pulse OFF portions 195, the plasma potential Vₚ remains at a typical plasma potential (e.g. 10-30V). This typical plasma potential Vₚ during the OFF portions 195 is insufficient to drive the plasma potential to the desired extraction potential and therefore the ions in the first plasma 115 do not have enough energy to pass through aperture 150 of extraction electrode 130 for implantation into substrate 140 housed within the second plasma chamber 125. However, during the pulse ON portions 190, the extraction voltage Vₑₓₜ applied to the first plasma chamber 120 by power source 182 drives the plasma potential Vₚ above the bias voltage applied using plasma source 110. This increase in plasma potential Vₚ accelerates ions 160 within plasma 115 to a desired implant energy. In this manner, the extraction voltage Vₑₓₜ applied to the walls of first plasma chamber 120 by power supply 180 controls the plasma potential in the first plasma chamber 120 relative to the extraction electrode 130 in order to create an attractive potential at the extraction electrode 130 for the plasma ions in the first plasma chamber 120. The accelerated ions cross plasma sheath 165 defined between plasma 115 and extraction electrode 130 and are directed toward substrate 140 through second plasma chamber 125 for implantation.

The type of ions 160 generated in plasma 115 may be controlled by the type of gas introduced into first plasma chamber 120. In addition, the depth of implantation into substrates 140 may be controlled by the implant energy of the ions 160 as well as the total dose of ions applied by power source 182. In the exemplary pulse train 185, the duty cycle of ON portions 190 may be greater than 50% and OFF portions 195 may be less than 50%. Thus, the bias voltage applied to first plasma chamber 120 may constitute a series of square wave pulses consisting of a series of high positive voltage levels 190 and a series of low or 0V portions 195. Alternatively, the extraction voltage Vₑₓₜ supplied by power source 182 may be DC which results in a 100% duty cycle. The ability to provide an increase in duty cycles provides increased thorough-put for the ion implantation apparatus 100.

In the exemplary embodiment shown in FIG. 1, the area proximate aperture 150 of extraction electrode 130 has a curved or angled profile portion 151 with respect to substrate 140. This directs the accelerated ions 160 aligned with aperture 150 of extraction electrode 130 into a parallel beam from first plasma chamber 120. Although neutrals present in plasma 115 may deposit on extraction electrode 130, the accelerated ions 160 generated during the modulated extraction voltage ON portions 190 of pulse train 185 may reduce and/or eliminate deposition and flaking formations present in the extraction region defined by the surface of the extraction electrode 130 facing first plasma chamber 120. This is due to the fact that some portion of the accelerated ions 160 having trajectories 151 that do not align with aperture 150 of extraction electrode 130 bombard the surface of the extraction electrode 130. This reduces or eliminates deposition and flaking formations on the surface of the extraction electrode 130 facing plasma 115. This minimizes maintenance and apparatus downtime to replace or clean extraction electrode 130. Moreover, since the extraction electrode 130 is at ground potential, the deleterious effects of secondary electrons resulting from ions implanting in the substrate 140 is potentially avoided.

FIG. 2 illustrates the ion implantation apparatus 100 shown in FIG. 1. As described above, power source 182 is configured to apply an extraction voltage to first plasma chamber 120 indicated by exemplary pulse train 185 shown in FIG. 1A to drive the plasma potential (Vₚ) to a desired extraction potential with respect to the extraction electrode 130 and substrate 140. Alternatively, the extraction voltage may also be a DC bias. The ON portions 190 of voltage pulse 185 applied to the walls of first plasma chamber 120 may be at a relatively high voltage in order to increase the plasma potential sufficiently to accelerate the ions in plasma 115 to a desired implant energy (e.g. 1-20 keV). Therefore, the high voltage (HV) stress region is inside the first plasma chamber. The first plasma chamber 120 is maintained at a high pressure, for example in the ˜mTorr range as indicated at reference 210. A plasma sheath region 165 is defined between the plasma boundary 166 and extraction electrode 130. This plasma sheath region 165 has a high electric field. The high pressure within the first plasma chamber 120 is regulated by the use of exhaust 108 and port 105 which defines the first pumping system associated with the first plasma chamber 120.

As mentioned above, the second plasma chamber 125 includes port 106 which extends from outer wall 125a to inner wall 125b through which a second gas with the desired properties, such as desired dopant properties or other properties, is introduced to generate second plasma 180. Exhaust port 107 extends from the inner wall 125b of second plasma chamber 125 through outer wall 125a. The second plasma chamber 125 is maintained at a relatively low pressure (e.g. in range of E−4 to E−5 Torr)) and is regulated by the use of exhaust 107 and gas inlet port 106. The differential pumping system defined by port 105 and exhaust 108 associated with chamber 120 and port 106 and exhaust 107 is configured to control gas breakdown in the respective chambers and enable independent plasma discharges in the two chambers. In addition, since the extraction electrode 130, second plasma chamber 125 and substrate 140 are maintained at ground potential, the electric field in the second plasma chamber is essentially a field-free region. Thus, the high voltage stress region is confined to the first plasma chamber 120.

In addition, the second plasma chamber 125 is maintained at a relatively low pressure, in the ˜E−4 to E−5 Torr range for example as indicated at reference 220. Thus, the pressure gradient is defined where the pressure changes from a relatively high pressure within first plasma chamber 120 to a relatively low pressure in the second plasma chamber 125. The width of aperture 150 in the y direction as well as the length of the aperture 150 in the x direction (also referred to as an aspect ratio) is relatively narrow so that the conductance of gas, such as dopant gas, from first plasma chamber 120 into second plasma chamber 125 is limited such that the pressure drop across extraction electrode 130 does not significantly impact the pressure gradient. This pressure gradient is down-stream of extraction electrode 130 where the electric field is essentially zero (i.e. where the second plasma chamber 125, extraction electrode 130 and substrate 140 are at ground potential). Since the pressure gradient is down-stream of extraction electrode 130, the first plasma chamber 120 and consequently the plasma 115 are not exposed to this pressure gradient. In this manner, the HV stress region of plasma formation in the first plasma chamber 120 is decoupled from the pressure gradient through which the extracted ions forming beam 155 are directed toward substrate 140 disposed within the second plasma chamber 125.

As noted above, in certain prior systems a coupling may occur between the plasma in a source chamber and a target substrate which causes source instability, extraction glitching and potentially beam current drift. As previously described, glitching is an interruption in beam current of the extracted ion beam. In contrast, the apparatus 100 of the present disclosure decouples the first plasma 115 generated in the first plasma chamber 120 in the HV stress region of plasma formation from the pressure gradient region through which the extracted ions are focused toward substrate 140. This provides for more stable system operation than previously considered and the deleterious effects of glitching are reduced. Thus, plasma operation may be stable at a given uniform pressure within first plasma chamber 120 and a relatively low pressure within second plasma chamber 125. Moreover, since the first plasma 115 is not exposed to this pressure gradient, parameters within the first plasma chamber 120 such as, for example, plasma density, ion and electron temperature, plasma potential etc., may be controlled by modulation of the potential Vₚ of the first plasma 115.

The second plasma 180 is a static neutral plasma confined in a magnetic or electrostatic field that provides a plasma lens to reduce the space charge forces of the ions that form ion beam 155 as well as making it possible to neutralize charge build-up on an exemplary insulating substrate 140 disposed with the second plasma chamber 125. In particular, the second gas supplied to the second plasma chamber 125 via port 106 is different from the first gas supplied to the first plasma chamber 120 and is configured to produce an inert plasma 180 within second plasma chamber 125. This inert plasma 180 may be the result of the introduction of inert gases, for example, Ar, Xe, etc., into the second plasma chamber 125 and the application of the applied RF signal generated by plasma source 145. Since the substrate 140 is disposed on platen 170 within the second plasma chamber 125, the substrate 140 which may be an insulating substrate, is immersed in the inert plasma 180. The neutrals and ionized species present in the second plasma 180 are at a relatively low pressure. The second plasma 180 may be a relatively low density plasma as compared to the first plasma 115. The plasma 180 provides charge neutralization of the ion beam 155. In other words, the beam 155 traveling through the second plasma chamber 125 has a natural divergence characteristic since the extracted ions have like charge and tend to repel each other as they travel toward substrate 140. However, the plasma density (np) of plasma 180 is greater than or equal to the density of beam 155 (nb) where np>nb. In addition, the edges of the beam 155 may be neutralized by the inert plasma 180, but is limited to the scale lengths of vb which is the speed of ion beam 155 and ωpe which is the plasma electron frequency of the electrons moving with beam 155 where vb/ωpe.

The first plasma chamber 120 is maintained at a relatively high pressure which accommodates efficient plasma ion generation to form accelerated ions 160. The second plasma chamber 125 is maintained at a relatively low pressure. This provides a relatively large ion to neutral mean collision distance which reduces scattering of the ions that form beam 155 as it travels through the second plasma chamber 125. As the ions 160 travel through the plasma 180, the charge of the ions that comprise beam 155 are partially neutralized. This reduces the divergence or increases the convergence of the ions of beam 155. Thus, the inert plasma within second plasma chamber 125 acts as a plasma lens by focusing or minimizing divergence of the ions that comprise ion beam 155 directed toward substrate 140. Additionally, the substrate 140 may be an insulating substrate where charge build-up may occur during implantation thereof. This may result in relatively high potential voltage on the substrate 140 leading to undesirable non-uniformities and possibly substrate damage. However, since the substrate 140 and second plasma chamber 125 are at ground potential providing a field free region around the substrate, as well as the use of an inert plasma as plasma 180, charge neutralization of the substrate 140 may be achieved.

In an alternative embodiment, the inert plasma 180 in the second plasma chamber 125 may be pulsed at the same frequency and duty cycle as the first plasma 115 in the first plasma chamber 120. In particular, power source 182 applies an extraction voltage Vₑₓₜ to drive the plasma potential (Vₚ) of plasma 115 to a desired energy level. This increase in plasma potential Vₚ accelerates ions 160 within plasma 115 to a desired implant energy. In this manner, the extraction voltage Vₑₓₜ applied to the walls of first plasma chamber 120 by power supply 180 controls the plasma potential in the first plasma chamber 120 relative to the extraction electrode 130 in order to create an attractive potential at the extraction electrode 130 for the plasma ions in the first plasma chamber 120. The accelerated ions cross plasma sheath 165 defined between plasma 115 and extraction electrode 130 and are directed toward substrate 140 through second plasma chamber 125 for implantation. A second gas is supplied to the second plasma chamber 125 to produce an inert plasma 180 within second plasma chamber 125 in response to the application of an applied RF signal generated by plasma source 145. Since the substrate 140 is disposed on platen 170 within the second plasma chamber 125, the substrate 140 which may be an insulating substrate, is immersed in the inert plasma 180. In the previous embodiments, the second plasma chamber was maintained at ground potential together with substrate 140. In this embodiment, the inert plasma in the second plasma chamber 125 may be pulsed at the same frequency and duty cycle as the extraction voltage applied to the walls of the first plasma chamber 120 where the rise time of each extraction voltage Vₑₓₜ pulse (e.g. ON portions 190) corresponds to the pulse applied to the walls of the second plasma chamber 125. This facilitates charge neutralization of an exemplary insulating substrate 140 during the ON portions of the pulse applied to the walls of the first plasma chamber 120 and the second plasma chamber 125.

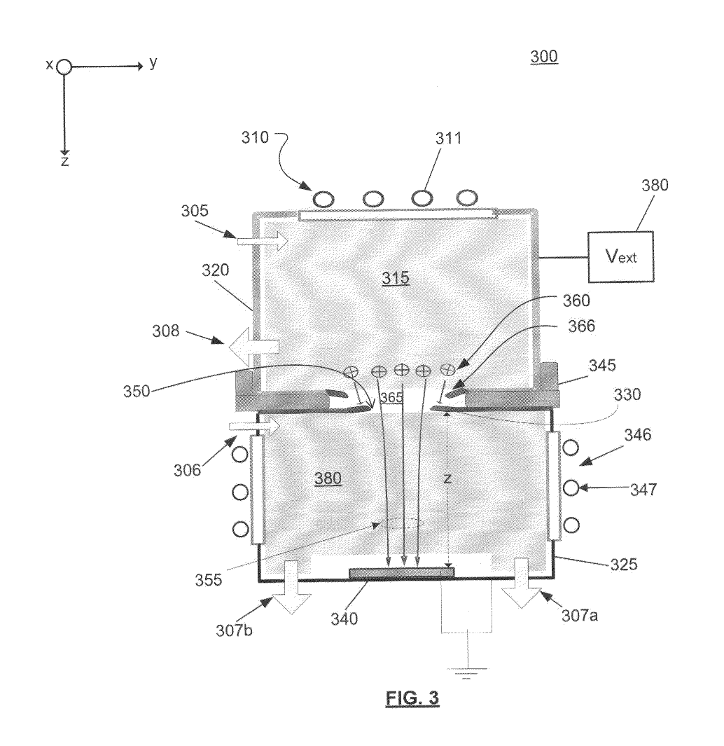

FIG. 3 is a schematic cross sectional view of an ion implantation apparatus 300 utilizing an alternative arrangement of the second plasma chamber 325 and in particular, RF plasma source 346. Similar to the ion implantation processing apparatus 100 shown in FIGS. 1 and 3, the apparatus 300 includes a first plasma chamber 320, a second plasma chamber 325 and an extraction electrode 330 disposed between the first and second plasma chambers. A first plasma 315 is generated within first plasma chamber 320 in response to an introduction of a gas to port 305 and the application of a RF discharge from exemplary plasma source 310 having RF antenna 311.

The extraction electrode 330 is disposed between the first plasma chamber 320 and the second plasma chamber 325. The extraction electrode 330 is electrically connected to the second plasma chamber 325 and includes aperture 350. An extraction voltage Vₑₓₜ is applied to the walls of first plasma chamber 320 by power supply 380 to increase the plasma potential in first plasma chamber 320 relative to the extraction electrode 330, which is at ground potential, in order to create an attractive potential at the extraction electrode 330 for accelerated plasma ions 360 in the first plasma chamber 320. The accelerated ions 360 cross plasma sheath 365 defined between plasma 315 and extraction electrode 330. The accelerated ions 360 that are aligned with aperture 350 of extraction electrode 330 are directed toward substrate 340 through second plasma chamber 325 and form ion beam 355 for implantation. The accelerated ions 360 that do not have trajectories that align with aperture 350 are prevented from entering second plasma chamber 325 by extraction electrode 330. These accelerated ions 360 bombard the surface of the extraction electrode 330 which reduces or eliminates unwanted deposition and flaking formations on the surface of the extraction electrode 330 facing plasma 315. The first plasma chamber 320 is maintained at a high pressure, for example in the ˜mTorr range and is regulated by the use of exhaust 308 and port 305 which defines the first pumping system associated with the first plasma chamber 320. The plasma sheath region 365 is defined between the boundary 366 of first plasma 315 and the extraction electrode 330.

The second plasma chamber 325 includes plasma source 346 used to generate second plasma 380 in response to the introduction of a gas within the chamber 325 via port 306. The plasma source 346 associated with the second plasma chamber 325 may be disposed on the sides of the chamber and may be an RF plasma source including RF antenna 347. The applied RF signal generated by the plasma source 346 may be pulsed or CW to generate the plasma 380 by RF discharge within second plasma chamber 325. The second plasma chamber 325 is maintained at a relatively low pressure as compared to the pressure of first plasma chamber 320 and is regulated by the use of a pair of exhaust ports 307a and 307b disposed at an end of the second plasma chamber 325 as well as second gas flow rate 306. A substrate 340 is disposed within the second plasma chamber 325. The substrate 340 may be a solar cell aligned a distance “Z” (the extraction gap) away from aperture 350 of extraction electrode 330 to undergo ion implantation. Ions 360 in plasma 315 that are accelerated ions in response to the applied extraction voltage Vₑₓₜ are directed through aperture 350 of extraction electrode 330 to form a beam 355. The beam 355 is directed through second plasma chamber 325 toward substrate 340. The extraction gap Z may be adjusted before and/or after crossover of the accelerated ions 360 that comprise beam 355.

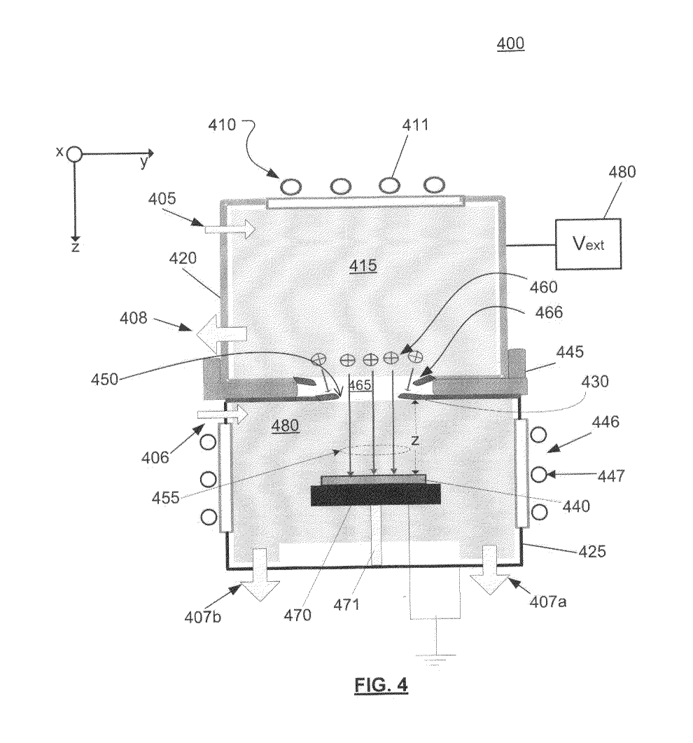

FIG. 4 is a schematic cross sectional view of an ion implantation apparatus 400 utilizing an alternative positioning of substrate 440 within second plasma chamber 425 to control the focusing of extraction ion beam 455 on the substrate. In particular, the extraction gap Z may be modified to control the trajectories of the extracted ions from diverging before impinging an upper surface of substrate 440 disposed within the second plasma chamber 425. As described above, an extraction voltage Vₑₓₜ is applied to the walls of first plasma chamber 420 by power supply 480 to increase the plasma potential in first plasma chamber 420 relative to the extraction electrode 430, which is at ground potential, in order to create an attractive potential at the extraction electrode 430 for the accelerated plasma ions 460 in the first plasma chamber 420. The accelerated ions 460 cross plasma sheath 465 defined between plasma 415 and extraction electrode 430. The accelerated ions 460 that are aligned with aperture 450 of extraction electrode 430 form ion beam 455 and are directed toward substrate 440 disposed within second plasma chamber 425. The substrate 440 may be disposed on platen 470 which is arranged within the second plasma chamber 425 by pedestal 471 to modify the extraction gap Z. The accelerated ions 460 that do not have trajectories that align with aperture 450 are prevented from entering second plasma chamber 425 by extraction electrode 430. Although the plasma 480 within second plasma chamber 425 is inert and reduces the divergence properties of the ions that comprise beam 455, the ions that comprise ion beam 455 have a natural divergence characteristic since the ions are “like charged” and tend to repel each other. By altering the positioning of substrate 440 within second plasma chamber 425, the extraction gap Z may be modified. This allows control of the divergence of the ion beam 455 relative to the substrate 440. In addition, by positioning the substrate 440 within the second plasma chamber 425 and exposing it to inert plasma 480, charge neutralization of the substrate is achieved. However, changes in extraction gap Z, ion divergence considerations, charge neutralization and beam current are some of the factors to be considered when determining optimum positioning of substrate 440 within second plasma chamber 425.

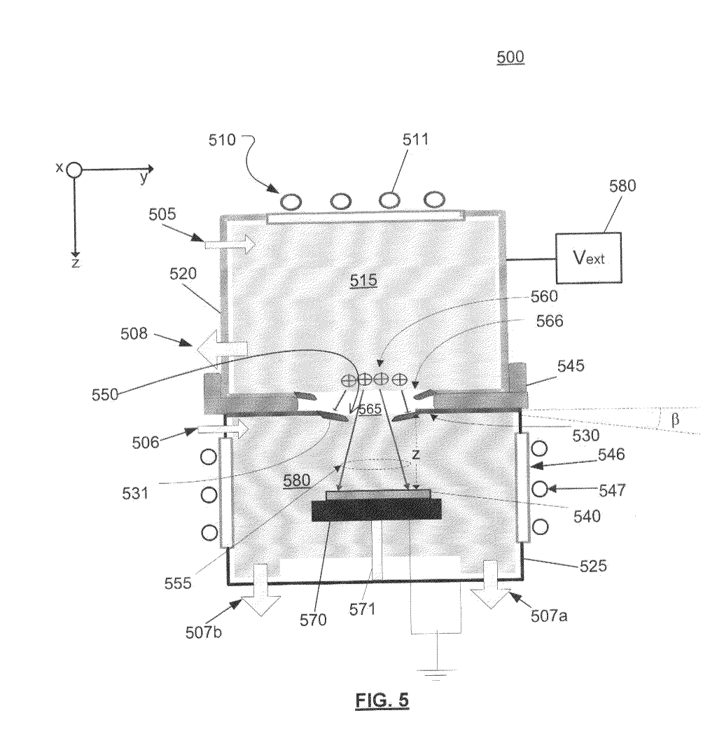

FIG. 5 is a schematic cross sectional view of an ion implantation apparatus 500 utilizing an alternative configuration of extraction electrode 540 to control ion beam 555 incident on substrate 540. In particular, extraction electrode 540 includes portion 531 which is angled with respect to a plane parallel to a plane of substrate 540. As described above, an extraction voltage Vₑₓₜ is applied to the walls of first plasma chamber 520 by power supply 580. This increases the plasma potential in first plasma chamber 520 relative to the extraction electrode 530, which is at ground potential, in order to create an attractive potential at the extraction electrode 530 for the accelerated plasma ions 560 in the first plasma chamber 520. The accelerated ions 560 cross plasma sheath 565 and the angled portion 531 of extraction electrode 530 proximate aperture 550 allows the accelerated ions 560 having trajectories that are aligned with the aperture to form ion beam 555.

Since the portion 531 of extraction electrode 530 has an angle β with respect to a plane parallel to substrate 540, the accelerated ions 560 having trajectories that are divergent from aperture 550 are directed toward substrate 550. Although the extraction electrode 530 is illustrated as having angled portions 531 with a particular angle β, the embodiments are not limited in this respect. The substrate 540 may be disposed on platen 570 and arranged within the second plasma chamber 525 by pedestal 571 to modify the extraction gap Z. The accelerated ions 560 that do not have trajectories that align with aperture 550 are prevented from entering second plasma chamber 525 by extraction electrode 530. In this manner, the extraction electrode 530 may be configured, proximate aperture 550 to control which accelerated ions 560 having particular trajectories are extracted from first plasma chamber 520. Thus, by modulating the plasma potential Vₚ based on the extraction voltage Vₑₓₜ applied to the walls of chamber 520 and by modifying the geometry of the extraction electrode 530 and by modifying plasma 515, the trajectory of the accelerated ions 560 and consequently the ion beam 555 extracted from plasma chamber 520 may be controlled.

Included herein is a flow chart representative of an exemplary process for utilizing the ion implantation apparatuses disclosed herein. While, for purposes of simplicity of explanation, the one or more processes shown herein, for example, in the form of a flow chart or logic flow are shown and described as a series of acts, it is to be understood and appreciated that the processes are not limited by the order of acts as some acts may, in accordance therewith, occur in a different order and/or concurrently with other acts from that shown and described herein. For example, those skilled in the art will understand and appreciate that a methodology could alternatively be represented as a series of interrelated steps. Moreover, not all steps illustrated in a methodology may be required for a novel implementation.

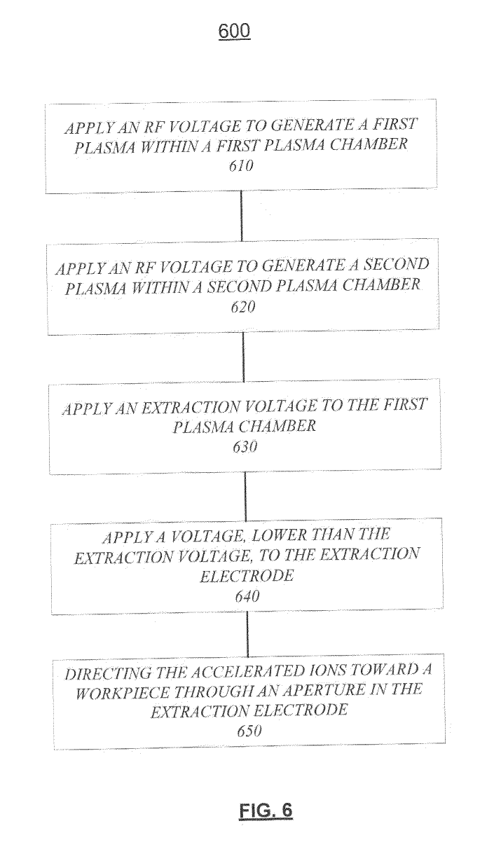

FIG. 6 illustrates a logic flow 600 consistent with use of ion implantation apparatuses disclosed herein. An RF voltage may be applied to generate a first plasma within a first plasma chamber at block 610. For example, in the ion implantation 100 shown in FIG. 1, a first plasma 115 is generated within first plasma chamber 120 in response to plasma source 110 and the introduction of a gas 105 supplied to first plasma chamber 120. An RF voltage may be applied to generate a second plasma within a second plasma chamber at block 620. For example, the second plasma chamber 125 is defined by an outer wall 125a and an inner wall 125b. The second plasma 180 is generated in response to the introduction of a gas within the inner wall 125b of the second chamber 125 via port 106 and the application of an RF signal. An extraction voltage is applied to the first plasma chamber to accelerate ions within the plasma at block 630. A voltage, lower than the extraction voltage, is applied to the extraction electrode and a workpiece disposed within the second plasma chamber at block 640. For example, the extraction electrode and workpiece may both be at ground potential. The accelerated ions are directed toward the work-piece through an aperture in the extraction electrode during application of the extraction voltage for implantation therein at block 650. For example, an extraction voltage Vₑₓₜ is applied to the walls of first plasma chamber 120 by power supply 180 to increase the plasma potential in first plasma chamber 120 relative to the extraction electrode 130, which is at ground potential, in order to create an attractive potential at the extraction electrode 130 for the accelerated plasma ions 160 in the first plasma chamber 120. The accelerated ions 160 cross a plasma sheath 165 defined between plasma 115 and extraction electrode 130. The accelerated ions 160 that are aligned with aperture 150 of extraction electrode 130 form ion beam 155 and are directed toward substrate 140 disposed within second plasma chamber 125.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. In particular, embodiments in which various configurations of extraction electrodes and plasma chamber in order to provide a desired ion beam for implantation into a substrate are possible. Moreover, an embodiment in which the plasma potential is modulated at various power levels and frequencies is also possible. In addition, embodiments are contemplated in which substrate movements can be either continuous for blanket implants or stepwise for selective emitter implantation. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Thus, the claims set forth below should be construed in view of the full breadth and spirit of the present disclosure as described herein.

What is claimed is:

1. An ion implantation apparatus, comprising:
a first plasma chamber operable to produce a first plasma in response to an introduction of a first gas by a first pumping system;
a second plasma chamber operable to produce a second plasma in response to an introduction of a second gas by a second pumping system; and
an extraction electrode, having an aperture, disposed between the first plasma chamber and the second plasma chamber, wherein the extraction electrode is electrically isolated from the first plasma chamber and is configured to allow accelerated ions from the first plasma to pass through the aperture for implantation into a substrate housed within the second plasma chamber, the accelerated ions in the first plasma are in response to an extraction voltage applied to the first plasma chamber.

2. The ion implantation apparatus of claim 1 wherein the first plasma chamber is at a first potential, and the extraction electrode, the second plasma chamber and the substrate are at a second potential that is negative with respect to the first potential.

3. The ion implantation apparatus of claim 1 wherein the extraction electrode is electrically isolated from the first plasma chamber by an insulated spacer.

4. The ion implantation apparatus of claim 1, wherein the extraction electrode has a curved profile proximate the aperture configured to control a trajectory of the accelerated ions toward the substrate.

5. The ion implantation apparatus of claim 1 wherein the first plasma includes dopant ions and the second plasma is an inert plasma.

6. The ion implantation apparatus of claim 1 wherein a plasma sheath is defined between the first plasma within the first plasma chamber and the extraction electrode, ions in the first plasma being accelerated across the sheath through the extraction electrode when the extractive voltage is applied to the first plasma chamber.

7. The ion implantation apparatus of claim 1 comprising a power source connected to the first plasma chamber configured to supply the extraction voltage to the first plasma chamber to accelerate the ions therein to a desired implant energy.

8. The ion implantation apparatus of claim 7 wherein the power source is positively pulsed defining a duty cycle having a pulse-ON period and a pulse-OFF period, the pulse-ON period corresponding to the extraction voltage applied to the first plasma chamber.

9. The ion implantation apparatus of claim 8 wherein the pulse-ON period has a pulse rise-time and a steady state duration and the pulse-OFF period has a pulse fall-time, the pulse rise-time plus the pulse fall-time being less than 25% of the pulse-ON state duration.

10. The ion implantation apparatus of claim 1 wherein the first plasma chamber is maintained at a first pressure and the second plasma chamber is maintained at a second pressure, the first pressure being greater than the second pressure.

11. The ion implantation apparatus of claim 1 further comprising a pumping system having an input port to the first plasma chamber and an exhaust port from the first plasma chamber, the input port configured to supply a first gas thereto and the exhaust port configured to regulate a pressure within the first plasma chamber.

12. The ion implantation apparatus of claim 11 wherein the pumping system is a first pumping system, the apparatus further comprising a second pumping system having an input port to the second plasma chamber and an exhaust port from the second plasma chamber, the input port configured to supply a second gas thereto and the exhaust port configured to regulate a pressure within the first plasma chamber.

13. The ion implantation apparatus of claim 1 further comprising a voltage source connected to the first plasma chamber configured to provide an RF bias voltage to the first plasma chamber to generate the first plasma.

14. The ion implantation apparatus of claim 1 further comprising a voltage source connected to the second plasma chamber configured to provide an RF bias voltage to the second plasma chamber to generate the second plasma.

15. A method of implanting a substrate in an ion implantation apparatus, comprising:
generating a first plasma within a first plasma chamber in response to an introduction of a first gas;
generating a second plasma within a second plasma chamber in response to an introduction of a second gas;
applying an extraction voltage to the first plasma chamber to accelerate ions within the first plasma;
electrically isolating the first plasma chamber from an extraction electrode disposed between the first plasma chamber and the second plasma chamber;
applying a voltage lower than the extraction voltage to the extraction electrode and the substrate disposed with the second plasma chamber, the accelerated ions directed toward the substrate through an aperture in the extraction electrode during application of the extraction voltage for implantation therein.

16. The method of claim 15 wherein the voltage applied to the extraction electrode, the second plasma chamber and the substrate is at ground.

17. The method of claim 15 further comprising controlling a trajectory of the ions toward the workpiece by providing the extraction electrode with a curved profile proximate the aperture.

18. The method of claim 15 further comprising accelerating the ions across a sheath defined between a boundary of the first plasma within the first plasma chamber and the extraction electrode.

19. The method of claim 15 further comprising:
regulating the first plasma chamber at a first pressure; and
regulating the second plasma chamber at a second pressure, the first pressure being greater than the second pressure.

20. The method of claim 19 wherein the first pressure in the first plasma chamber is regulated by a first pumping system connected to the first plasma chamber and the second pressure in the second plasma chamber is regulated by a second pumping system connected to the second plasma chamber.

21. The method of claim 15 wherein the first gas and the second gas are different, the first gas configured to provide dopant ions, and the second gas configured to provide an inert plasma as the second plasma within the second plasma chamber.
